(19) United States
(12) Patent Application Publication
(10) Pub. No.: US 2006/0048700 A1
(43) Pub. Date: Mar. 9, 2006

(54) Method for achieving device-quality, lattice-mismatched, heteroepitaxial active layers

(76) Inventors: Mark W. Wanlass, Golden, CO (US); Phillip S. Ahrenkiel, Wheatridge, CO (US)

Correspondence Address: Paul J White;NREL, 1617 Cole Blvd, Golden, CO, 80401, US

(21) Appl. No.: 10/526,785

(22) PCT Filed: Sep. 5, 2002
(86) PCT No.: PCT/US02/28314

§ 371 Date: Mar. 4, 2005

(51) Int. Cl. C30B 23/00; C30B 25/00; C30B 28/12; C30B 28/14

(52) U.S. Cl. 117/84

(57) ABSTRACT

A method is provided for achieving device-quality active layers in lattice-mismatched-heteroepitaxial systems. The method eliminates strain and dislocations resulting from lattice mismatch with respect to the substrate (12) of a heteroepitaxial active layer (14). The optimized heterostructure comprises a substrate (12), a compositionally step-graded region terminated with a buffer layer (14), an intermediate region (16), an active layer (18), and a capping layer (20). Concepts of the invention are demonstrated in douple heterostructures containing the semiconductor alloys GaₓIn₁₋ₓAs and InAs_{y}P_{1-y}.

### CONTRACTURAL ORIGIN OF THE INVENTION

The United States Government has rights in this invention under Contract No. DE-AC36-99GO10337 between the U.S. Department of Energy and the National Renewable Energy Laboratory, a division of Midwest Research Institute.

### TECHNICAL FIELD

This invention relates generally to heteroepitaxial lattice-mismatched systems and, more particularly, it relates to optimizing the material quality of an active region that is lattice-mismatched to a particular substrate. The invention uses a compositional step-grade that is terminated with a strained buffer layer correctly lattice-matched to the active layer of interest. An intermediate region serves to isolate the active layer from the underlying misfit-dislocation networks, and to prevent threading dislocations from reaching the active region.

### BACKGROUND ART

Lattice-mismatched heteroepitaxy offers numerous film/substrate combinations for semiconductor device design. Many applications require optically thick, mismatched films with device-quality electronic properties, such as adequate minority-carrier lifetime. However, strain relaxation generates dislocations that limit carrier-transport behavior via Shockley-Read-Hall recombination. Residual strain can also deteriorate surface planarity and cause wafer bowing, hindering processing control. Fundamental studies have identified the benefits of multilayers and lattice-mismatched heterointerfaces to filter threading dislocations and control the formation of misfit-dislocation networks that promote relaxation. Here, we describe improved methods to eliminate strain in a lattice-mismatched active layer, to remove misfit dislocations from the vicinity of the active layer, and to prevent threading dislocations from extending into the active layer.

In the field of lattice-mismatched heteroepitaxial multilayer growth and design, it is standard practice to grow structures containing the following elements: (a) a crystalline substrate, (b) a compositionally step-graded region that contains multiple layers of an alloy material and that is terminated with a buffer layer of extended thickness, (c) an active layer of a material that is lattice-mismatched to the substrate, and (d) a thin capping layer. Moreover, it is also standard practice to select the alloy composition of the buffer layer material such that the lattice constant of the buffer layer when fully relaxed of strain is matched to that of the active layer material when fully relaxed of strain. The buffer layer displaces the active layer from the underlying misfit dislocation networks, which generate inhomogenous strain fields, and also limits the propagation of threading dislocations, which typically decrease in density as the layer thickness is increased.

However, it is also widely accepted from both experimental and theoretical grounds that the strain relaxation in epitaxial films is generally incomplete. In particular, the near-surface region of a compositional grade generally retains significant strain. Strain alters the lattice spacing of the buffer layer material and, correspondingly, affects the optimal buffer alloy composition for lattice matching to the active layer.

Lattice mismatch among electronic materials remains a primary limitation in the design of high-performance, thin-film devices. Many applications require deposition of a material with a particular physical property, such as the optical bandgap for light absorption or emission. Heteroepitaxy uses the structure of the substrate surface as a crystallographic template for nucleation and growth of thin films with high material quality. Although the constituent materials may have similar crystal structures parallel to the growth plane, slight differences in their bulk lattice parameters introduces lattice mismatch that is accommodated by a combination of strain and dislocations.

The equilibrium structures of most tetrahedral semiconductor materials can be described in terms of a single, cubic lattice parameter. The cubic lattice parameters of the pseudobinary semiconductor alloys vary with composition. The bulk misfit f of an epitaxial film is defined in terms of the equilibrium film and substrate lattice constants, a and aₛ, respectively, as:
f≡a/aₛ−1 (1).

In practice, a compositionally graded region and/or buffer layer can be used to provide a “virtual” substrate with the desired lattice constant for subsequent deposition of an active layer. Relaxation occurs within the graded region, with both a corresponding diminution of structural coherence in electronically inactive depths of the film, and the generation of undesirable topography and threading dislocations. The extent and mechanisms of layer relaxation are sensitive to the particular mechanical properties and growth conditions of the constituent materials.

Biaxial strain arises in lattice-mismatched thin films of semiconductor alloys. The in-plane component of the strain field (parallel to the growth plane) is given by
ε^{(∥)}=a^{(∥)}/a−1 (2)
where a^{(∥)} is the in-plane lattice parameter for the strained layer.

The in-plane misfit, which is an indication of the coherence between the film and substrate, is defined as:
f^{(∥)}≡a^{(∥)}/aₛ−1≈f+ε^{(∥)} (3)
where the approximation is made to first order in ε^{(∥)}. The quantity f^{(∥)} differs from the bulk misfit in the presence of strain, and is proportional to the misfit dislocation density at the film/substrate interface.

In the prior art for the design of lattice-mismatched heterostructures, the bulk lattice constant of the buffer layer is lattice-matched to that of the active layer. Although, coherence is maintained between the active layer and the buffer layer in the prior art, residual strain adversely affects the planarity of the epitaxial growth surface, limiting the maximum allowable film thickness. Accordingly, a need exists to accomodate strain in a manner that does not generate undesirable surface topography. Further, the active layer should be structurally isolated from the graded region to reduce the influence of misfit dislocations on the active layer, and to reduce the density of threading dislocations that penetrate the active layer.

These objectives are accomplished in the present invention by identifying that the optimal alloy composition of the buffer layer is that which, when in a state of strain induced by epitaxial growth, has a lattice constant parallel to the substrate that is equal to that of the unstrained active layer. Furthermore, an intermediate region between the buffer layer and the active layer is included, which serves to displace the active layer from the graded region, thereby reducing the influence of underlying dislocations on the active layer.

GaₓIn₁₋ₓAs is used for a number of low-bandgap device applications, including thermophotovoltaic power generation. Lattice-matched GaₓIn₁₋ₓAs (x=0.47) double heterostructures (DHs) on InP show minority-carrier lifetimes typically in the range of ˜10-20 μs. An appropriate partner alloy is required for forming DHs on InP containing low-bandgap, lattice-mismatched GaₓIn₁₋ₓAs (x<0.47). InAs_{y}P_{1-y} is an ideal candidate for compositional grading from InP substrates, and provides carrier confinement and surface passivation to GaₓIn₁₀₋ₓAs, with optical transparency for infrared applications. This invention provides specific criteria for the structural optimization of GaₓIn₁₋ₓAs/InAs_{y}P_{1-y} DHs grown on InP substrates using a compositional grade with a strained buffer layer.

### DISCLOSURE OF THE INVENTION

The present invention discloses a heterostructure and a method for minimizing dislocations and residual strain resulting from lattice mismatch of a heteroepitaxial layer. The method comprises providing a substrate, depositing a compositionally step-graded region on the substrate, terminating the step-grade with a a buffer layer of extended thickness, depositing an intermediate region on the buffer layer, depositing an active layer on the intermediate region, and depositing a capping layer on the active layer.

The method uses a buffer layer of selected alloy composition. The buffer layer is in a state of biaxial strain that causes the in-plane lattice constant of the buffer layer to match precisely the unstrained lattice constant of the active layer. An intermediate region containing a displacement layer is inserted between the buffer and active layers to spatially separate the active layer from the misfit dislocation networks that reside in the graded region, and to limit the propagation of threading dislocations into the active region.

The elimination of residual strain within the active layer is desirable for developing complex multilayer heterostructures, such as tandem thermophotovoltaic devices.

An example of the present invention is given as illustration. Specific optimization criteria are given for a heterostructure containing the semiconductor alloys GaₓIn₁₋ₓAs and InAs_{y}P_{1-y} in a configuration that is designed to (i) eliminate strain in the GaₓIn₁₋ₓAs active layer, and (ii) eliminate dislocations from the GaₓIn₁₋ₓAs active layer. General criteria are then discussed for the selection of design parameters for arbitrary lattice-mismatched systems.

### BRIEF DESCRIPTION OF THE DRAWINGS

The accompanying drawings, which are incorporated in and form apart of the specification, illustrate the preferred embodiments of the present invention, and together with the descriptions serve to explain the principles of the invention.

### IN THE DRAWINGS

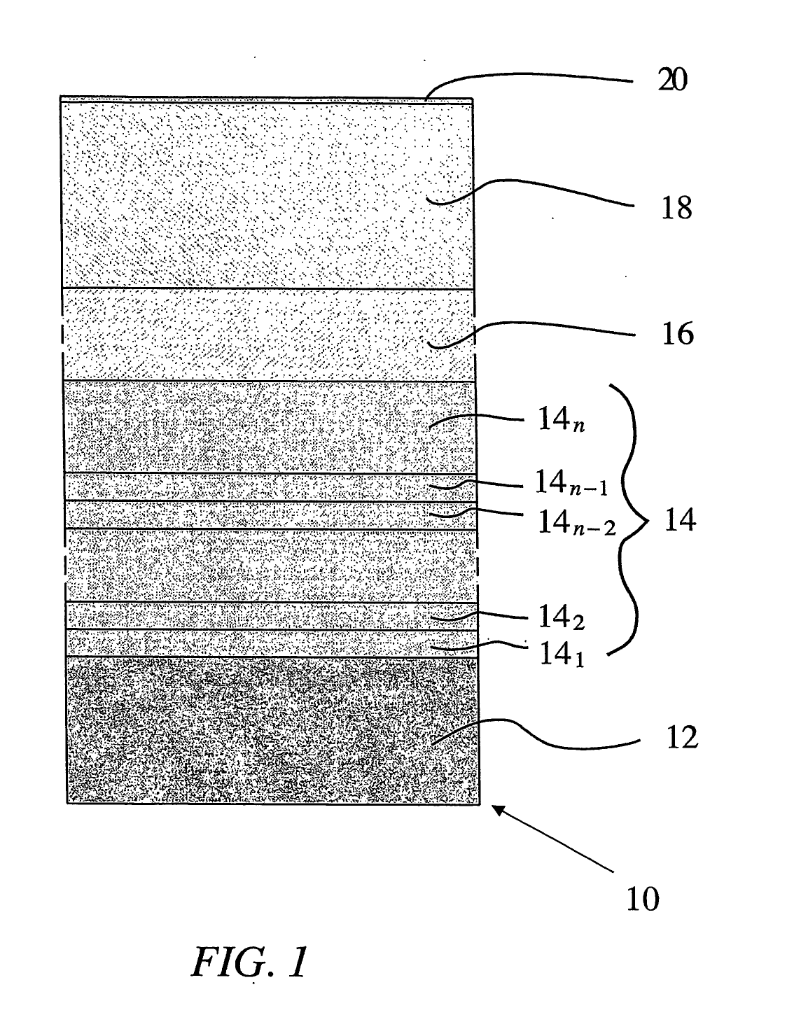

FIG. 1 is a sectional view illustrating a semiconductor consisting of a semi-insulating substrate, a compositionally step-graded region containing a buffer layer, an intermediate region, an active layer, and a thin capping layer, constructed in accordance with the present invention;

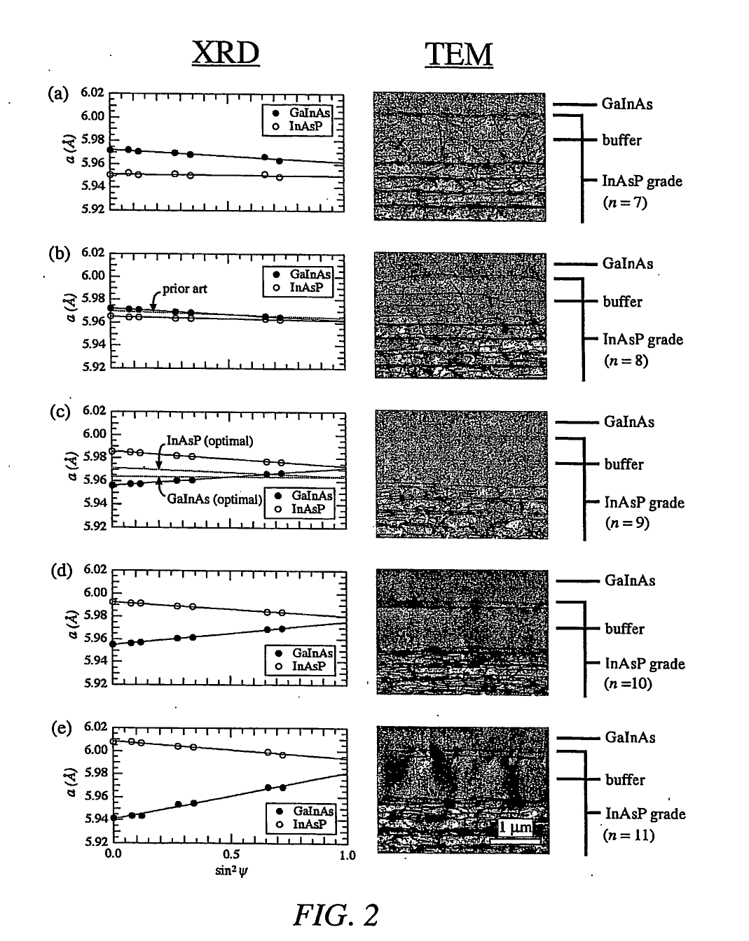

FIG. 2 is a composite depicting the results of X-ray diffraction measurements of the lattice constant a(ψ) vs. sin²ψ, where ψ is the tilt from the substrate normal, for five different GaₓIn₁₋ₓAs (GaInAs) active layers and the underlying InAs_{y}P_{1-y} (InAsP) buffer layers, and the transmission electron micrographs showing the dislocation morphology in the vicinity of the interface between the GaInAs active layer and the buffer layer. The data are identified by the number of steps n in the grade: a) n=7, b) n=8, c) n=9, d) n=O, and e) n=11;

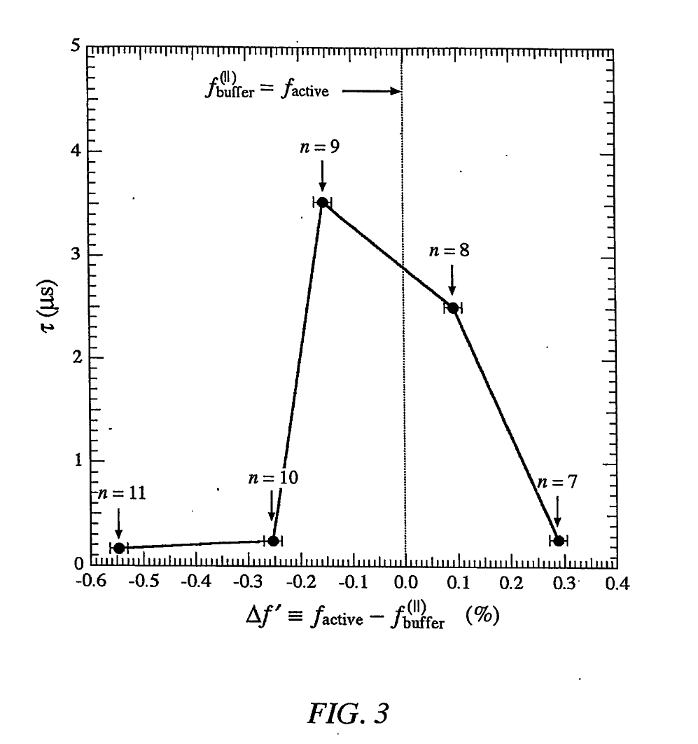

FIG. 3 is a graph illustrating minority-carrier lifetime τ measured by photoconductive decay vs. Δf′ measured by X-ray diffraction;

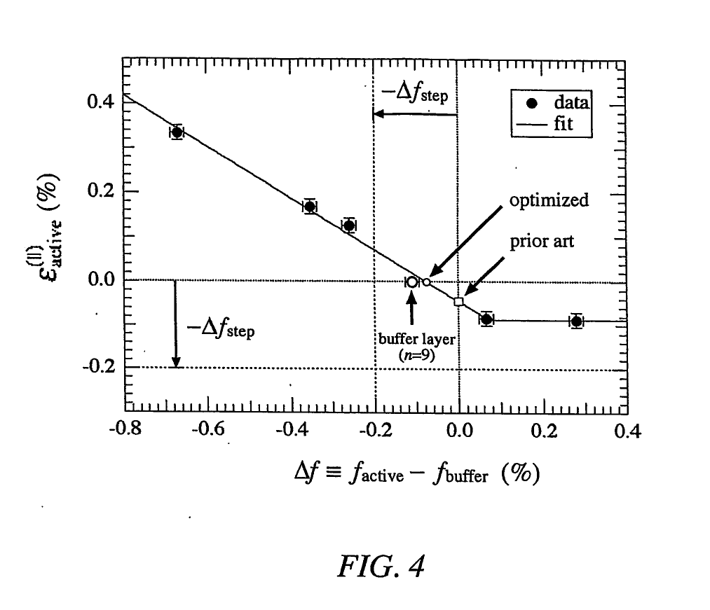

FIG. 4 is a plot of the experimental strain in the GaₓIn₁₋ₓAs active layer vs. Δf. The solid line through the data is a least-squares fit. The small open circle indicates the optimized structure; the small open square indicates the prior art.

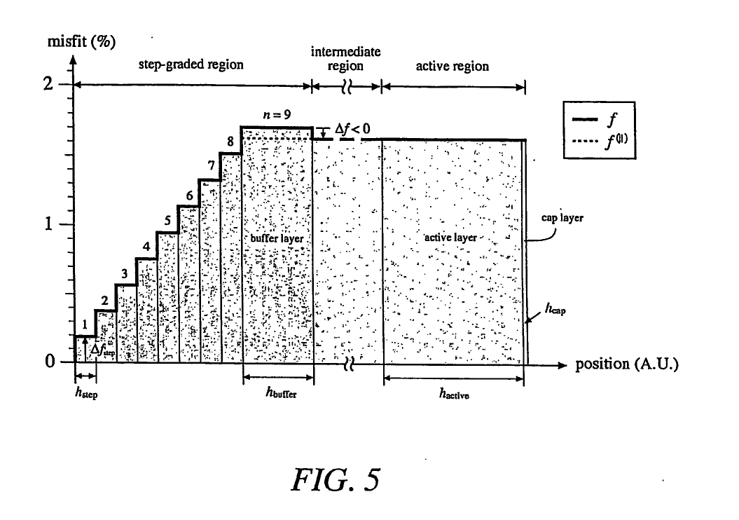

FIG. 5 is a graph of idealized misfit profiles for an optimized DH showing the bulk, unstrained misfit f for the fully relaxed layers, and the strained, in-plane misfit f^{(∥)} as functions of position with respect to the substrate surface using the optimized heterostructure design; and

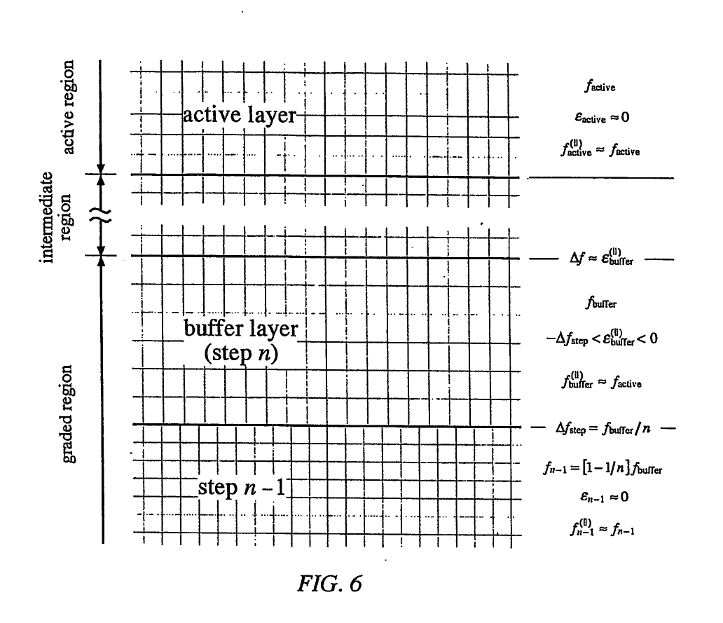

FIG. 6 is a schematic diagram illustrating the invention concept: A strained buffer layer provides a lattice-matched template for the coherent growth of an unstrained active layer. An intermediate region is inserted between the step-graded and active regions for structural isolation. The thin, cross-hatched lines represent crystallographic planes. The partially coherent interface structure below the buffer layer has been simplified for clarity. Relevant parameteric relationships corresponding to various layers and interfaces are listed to the right of the diagram.

### DETAILED DESCRIPTION OF THE PREFERRED EMBODIMENTS

As illustrated in FIG. 1, DHs containing the semiconductor alloys GaₓIn₁₋ₓAs and InAs_{y}P_{1-y} on DIP substrates, indicated generally at 10, are prepared by metalorganic vapor-phase epitaxy (MOVPE). The structures are designed with the following components: (a) a semi-insulating InP substrate 12, (b) a compositionally step-graded layer of InAs_{y}P_{1-y} 14 having layers 14₁ to 14ₙ, where layer 14ₙ serves as the buffer layer, (c), a displacement layer 16, (d) an active layer of GaₓIn₁₋ₓAs 18, and (f) a thin capping layer of InAs_{y}P_{1-y} 20. The substrate 12 is of known composition and can be obtained from a commercial source. The composition y of the InAs_{y}P_{1-y} step-grade 14 is varied incrementally to accommodate the majority of the mismatch. The InAs_{y}P_{1-y} buffer layer 14ₙ is grown to a thickness of about one (1) μm. The intermediate region 16 containing the displacement layer is deposited on the buffer layer. The GaₓIn₁₋ₓAs active layer 18 is deposited on the intermediate region. The InAs_{y}P_{1-y} cap 20 is grown to a thickness of about 300 Å and provides electrical passivation and carrier confinement.

Investiagation of GaInAs/InAsP DHs

Accompanying experiments were performed to demonstrate several concepts of this invention. The experimental techniques and results are described below.

Experiment

MOVPE growth of GaₓIn₁₋ₓAs/InAs_{y}P_{1-y} heterostructures was conducted on two-inch (2″) Fe-doped, epi-ready InP semi-insulating substrates (aₛ=5.869 Å) obtained from Wafer Technology, Ltd. or other commercial vendor. The orientation of the substrates is 2° off [001] toward [101]. The samples were inductively heated in purified hydrogen to 620° C. with an ambient pressure of 650 torr. All layers were grown without interrupts using a constant trimethylindium flow rate. InAs_{y}P_{1-y} was grown with a fixed flow rate of phosphine, with the composition y controlled by varying the arsine flow rate. An alternate flow of trimethylgallium is used to grow GaₓIn₁₋ₓAs in the 0.5-eV bandgap range at a typical rate of 5-6 μm/h.

Minority-carrier lifetimes were measured by photoconductive decay (PCD) using inductive coupling at ultra-high frequencies between each sample and a copper-coil antenna. Excitation was provided by a pulsed yttrium-aluminum-garnet laser at 1064 nm. The lifetimes reported here were evaluated under low-injection conditions.

Transmission electron microscope (TEM) samples were prepared on Cu grids in [110] cross section by polishing, dimpling, and Ar ion milling at low angle (8°-14°) with sector control and liquid N₂ cooling. TEM data were acquired on a Philips CM 30 operated at 300 kV with a LaB₆ filament and equipped with a 14-bit digital camera. Dark-field images using the <220> in-plane reflections clearly reveal dislocations with sufficient chemical contrast to locate heterointerfaces.

The strain of epitaxial layers was determined using the lattice spacings measured in X-ray diffraction (XRD) θ/2θ scans of collections of asymmetric and (nearly) symmetric reflections. In particular, the (h0l) reflections were used, which are oriented in the plane containing the substrate normal and [001]. The XRD patterns were measured on a Scintag X1 powder diffractometer. Variation in the lattice constant with tilt ψ from the substrate normal reveal biaxial strain. The magnitude of the reciprocal lattice vector g corresponding to the reflection (hkl) can be written as

$$g = \frac{\sqrt{{h}^{2} + {k}^{2} + {l}^{2}}}{a ( ψ )} , \qquad ( 4 )$$

where the “strained” lattice constant a(ψ) for the cubic crystal at tilt ψ has the form:
a(ψ)=a^{(⊥)}+[a^{(∥)}−a^{(⊥)}]sin²ψ (5)
The end-points a^{(∥)} and a^{(⊥)} are the lattice constants parallel and perpendicular to the substrate plane, respectively, and are determined by linear least-squares fit of a(ψ) with respect to sin²ψ. The equilibrium lattice constant and composition are extracted by relating a^{(∥)} and a^{(⊥)} for a semiconductor alloy film in a biaxial strain field. Elastic constants for the alloys are linearly interpolated from the end-point binary compounds. The alloy lattice constants and misfit to InP also vary linearly with composition, and can be computed using the degrees of misfit f_{InAs}=3.231% and f_{GaAs}=−3.674% for the end-point compounds.
Strain and Microstructure

A series of samples with approximately fixed GaₓIn₁₋ₓAs composition was grown to cover a range of buffer compositions. The number of steps in the InAs_{y}P_{1-y} grade was varied among the samples, with a nominal misfit increment of 0.20% per step, so that the last step comprised a buffer with the desired composition. The step thickness was 0.3 μm, and the buffer layers were 1 μm thick.

XRD provides a quantitative determination of strain, composition, and interfacial coherence, as illustrated in FIG. 2. The variations in strain of the buffer and active layers are readily apparent as the number of steps and buffer-layer composition are altered (see Table 1 below).

TABLE 1
GaInAs/InAsP DH composition and structure properties.

| | | InAs_{y}P_{1-y} Buffer Layer | | | GaₓIn₁₋ₓAs Active Layer | | |
|---|---|---|---|---|---|---|---|
| Sample | n | y | f (%) | ε^{(∥)} (%) | x | f (%) | ε^{(∥) (%)} |
| 1-510 | 7 | 0.432 | 1.394 | −0.011 | 0.226 | 1.672 | −0.087 |
| 1-509 | 8 | 0.499 | 1.612 | −0.027 | 0.225 | 1.677 | −0.083 |
| 1-511 | 9 | 0.582 | 1.880 | −0.102 | 0.233 | 1.621 | 0.127 |
| 1-588 | 10 | 0.619 | 2.002 | −0.097 | 0.229 | 1.648 | 0.169 |
| 1-590 | 11 | 0.695 | 2.246 | −0.120 | 0.240 | 1.576 | 0.335 |

The variation in dislocation morphology between the GaₓIn₁₋ₓAs and the InAs_{y}P_{1-y} buffer is clearly evident from the TEM images. Misfit dislocations develop at the GaₓIn₁₋ₓAs/InAs_{y}P_{1-y} heterointerface as the structure deviates from the optimal design. In all cases, threading dislocation densities typically remain small in these active layers. This dislocation barricading may partly stem from an increased microhardness of GaₓIn₁₋ₓAs with respect to InAs_{y}P_{1-y} at the relevant compositions.

Recombination and Interface Properties

The inventors of the present invention have discovered that matching the in-plane lattice constant of the buffer layer to the bulk lattice constant of the active layer can improve the material quality of the active layer. Corresponding improvement in minority-carrier lifetime result from the elimination of misfit dislocations, which act as recombination centers. Minority-carrier lifetime serves as a reliable indicator of device performance, without the need for additional processing.

The bulk misfit difference acrross the heterointerface between the active layer and the buffer layer is:
Δf≡f_{active}−f_{buffer} (6)

The in-plane misfit difference is an indication of the incoherence between the active layer and the buffer layer:

$$Δ {f}^{( ‖ )} ≡ {f}_{active}^{( ‖ )} - {f}_{buffer}^{( ‖ )} . \qquad ( 7 )$$

In fact, good coherence between the film and buffer (Δf^{(∥)}≈0) can be achieved over a relatively broad range of buffer-layer compositions. However, strain is introduced in the active layer as the buffer composition deviates from the optimal value. The optimized buffer is one that minimizes the magnitude of the difference between the bulk misfit of the active layer and the in-plane misfit of the buffer layer:

$$Δ {f}^{′} ≡ {f}_{active} - {f}_{buffer}^{( ‖ )} , \qquad ( 8 )$$

which vanishes for the optimized structure.

The minority-carrier lifetime and these interfacial parameters are listed in Table 2. The variation in τ with Δf′ is shown in FIG. 3.

TABLE 2
GaInAs/InAsP DH recombination and interface properties.

| n | τ (μs) | Δƒ (%) | Δƒ^{(∥) (%)} | Δƒ′ (%) |
|---|---|---|---|---|
| 7 | 0.264 | 0.278 | 0.199 | 0.288 |
| 8 | 2.512 | 0.065 | 0.008 | 0.092 |
| 9 | 3.527 | −0.259 | −0.027 | −0.155 |
| 10 | 0.243 | −0.354 | −0.082 | −0.254 |
| 11 | 0.163 | −0.670 | −0.207 | −0.547 |

Structural Optimization

We now specify that the optimal structure satisfies

$$Δ {f}^{′} = 0 ( {f}_{buffer}^{( ‖ )} = {f}_{active} ) .$$

Thus, the bulk misfit difference in the optimized structure is approximately

$$Δ {f}_{opt} \approx {ɛ}_{buffer}^{( ‖ )} .$$

Stated in other words, the optimal buffer misfit is f_{buffer}=f_{active}−Δfₒₚₜ.

We further stipulate that the active region should be spatially displaced from the step-grade region to limit the influence of dislocations on the material quality of the active layer.

We first apply these criteria to the GaₓIn₁₋ₓAs/InAs_{y}P_{1-y} DHs presented here, based on empirical results. We then extend the method to arbitrary mismatched systems. Additional considerations on the selection of the structural design parameters are discussed lastly.

Specific Considerations for GaInAs/InAsP DHs

The experimental variation in strain of the active layer ε_{active}^{(∥)} with the misfit difference Δf is well-described by a region of constant strain, and an adjacent region over which the strain varies linearly with Δf [FIG. 4]. An additional InAs_{y}P_{1-y} buffer-layer sample grown without the GaₓIn₁₋ₓAs active layer and cap illustrates continuity of the trend near the optimal condition, as indicated on the graph. The composition and structure of this sample are listed in Table 3.

TABLE 3
InAsP buffer-layer composition and structure.

| Sample | n | y | ƒ (%) | ε^{(∥)} (%) |
|---|---|---|---|---|
| 1-707 | 9 | 0.586 | 1.895 | −0.104 |

The optimized structure and the prior art for the GaInAs/InAsP DHs under consideration can be identified emprically from the intersections of the curve fit with the horizontal and vertical axes, respectively. The optimal mismatch difference is found to be Δfₒₚₜ=(−0.075±0.016)%. The anticipated strain in the active layer using the prior art (Δf=0) is ε_{active}^{(∥)}=(−0.044±0.011)%.

A quantitative description of the optimized GaₓIn₁₋ₓAs/InAs_{y}P_{1-y} heterostructure is now provided. Consider, as a particular example, a GaₓIn₁₋ₓAs active layer with composition x_{active}=0.233 (f_{active}=1.621%) and thickness h_{active}=2 μm [FIG. 5].

The optimal InAs_{y}P_{1-y} buffer has thickness h_{buffer}=1 μm and misfit f_{buffer}=1.696%. The corresponding composition is y_{buffer}=0.525.

The InAs_{y}P_{1-y} compositional grade contains nine steps (n=9) with step thickness hₛₜₑₚ=0.3 μm. A uniform mismatch increment of Δfₛₜₑₚ=0.188% is maintained within the grade, repesenting a compositional increment of Δyₛₜₑₚ=0.058.

An intermediate region is inserted between the active layer and buffer layer that is constructed, for simplicity, of a uniform InAs_{y}P_{1-y} displacement layer with composition y=0.502 (f=1.621%) and thickness h=1 μm.

The active layer is capped with a thin, pseudomorphic InAs_{y}P_{1-y} layer.

General Design Considerations

The concept of the invention can be stated without reference to the specific materials used here for demonstration. Accompanying deposition techniques and calibration procedures must be established for other constituent alloys of choice to understand the relevant growth and strain-relaxation behavior. Whereas a fully optimized structure may deviate from the specifications given here, these general criteria provide an optimization approach with a minimum number of optimization parameters.

We now describe a generic, optimized heterostructure [FIG. 6] deposited on an arbitrary substrate. The alloys are identified only by the mismatch with respect to the substrate, but specific deformation and relaxation properties are not mentioned. For simplicity, and without loss of generality, the sign of the misfit is assumed to be positive.

Construction of the optimized, lattice-mismatched heterostructure is initiated by depositing n compositional steps, with the first n-1 steps having equal thickness hₛₜₑₚ, which is limited by the allowable net thickness and growth time.

The final step (step n) of the grade forms the buffer layer, with misfit f_{buffer} and thickness h_{buffer}. The thickness of the buffer is extended, such that h_{buffer}≧hₛₜₑₚ, to control the degree of strain in the buffer layer, as needed. A uniform mismatch increment of Δfₛₜₑₚ=f_{buffer}/n is maintained in the grade, such that the misfit of step m (where m=1 . . . n) is given by fₘ=(m/n)f_{buffer}. For example, step n-1 should have misfit fₙ₋₁=(1−1/n)f_{buffer}.

The active layer has bulk misfit f_{active}, and is of arbitrary thickness h_{active}. The active layer is unstrained (ε_{active}≈0) in the optimized structure, with in-plane misfit

$${f}_{active}^{( ‖ )} \approx {f}_{active} .$$

Strain is eliminated in the active layer by selecting the parameters n, f_{buffer} and h_{buffer} such that

$${f}_{buffer}^{( ‖ )} \approx {f}_{active} ( {f}^{′} = 0 ) .$$

The intermediate region contains a displacement layer that is lattice-matched to the active layer. The displacement layer may also contain a number of suitable heterointerfaces designed to limit dislocation propagation into the active region.

The capping layer is also lattice-matched to the active layer.

Additional Design Considerations

It is observed in linearly step-graded structures of comparable specifications to those described here that, following the deposition of a particular individual step of the graded region, that step may be driven to a condition of nearly complete strain relaxation as grading proceeds by the deposition of subsequent steps. For example, it is anticipated that layer n-1 relaxes during growth of the buffer layer, such that

$${f}_{n - 1}^{( ‖ )} \approx {f}_{n - 1} .$$

This allows the extension of the optimized structure described here to a broadened compositional range.

It is anticipated that layer n-1 relaxes during growth of the buffer layer, such that

$${f}_{n - 1}^{( ‖ )} \approx {f}_{n - 1} .$$

Upon reaching sufficient thickness, the buffer layer partially relaxes to an in-plane mismatch of

$${f}_{buffer}^{( ‖ )} > {f}_{n - 1} .$$

The strain the buffer generally lies in the range

$$- Δ {f}_{step} < {ɛ}_{buffer}^{( ∥ )} < 0.$$

Thus, the full utility of the step-grade is realized when the misfit of step n-1 is less than that of the active layer (i.e., fₙ₋₁<f_{active}).

Stated in other words, the bulk misfit difference between the buffer layer and active layer to acheive the optimal condition Δf′=0 should be

$$Δ f \approx {ɛ}_{buffer}^{( ∥ )} .$$

Therefore, Δf is restricted to the range −Δfₛₜₑₚ<Δf<0 in the optimized structure.

From the previous discussion, it is evident that f_{buffer} should differ from f_{active} by a fraction of Δfₛₜₑₚ to achieve proper lattice-matching between the buffer layer to the active layer.

The optimized buffer provides a surface upon which a strain-free active layer can be deposited without misfit dislocations. This condition is desirable for an number of applications that require layers of high material quality. The unstrained configuration of the active layer engineered by this invention can, in principle, be maintained to unlimited thickness of the active layer, provided that the strain in the buffer layer remains constant as subsequent layers are deposited. Moreover, this invention can be applied to a variety of mismatched systems by substitution of the relevant substrate and alloy materials and structural specifications.

If the active layer and buffer layer are composed of different alloy systems (such as GaₓIn₁₋ₓAs/InAs_{y}P_{1-y}), dislocation propagation and strain relaxation can be affected by the discontinuity in the elastic properties, and growth behavior across the heterointerface. Further, if the film and buffer are composed of different alloy systems, adjustments in the target compositions may be required to compensate for differences in thermal expansion among the constituent alloys. In general, the alloy material of the step-graded and intermediate regions may be tailored to accomodate the deposition of a specific lattice-mismatched crystal material on a suitable substrate. In addition, the intermediate region may incorporate multilayers of appropriate alloy materials in a configuration designed to prevent threading dislocations from reaching the active region.

### SUMMARY

In sum, the method of the present application is explored using GaₓIn₁₋ₓAs/InAs_{y}P_{1-y} DHs grown on InP substrates. The DH structure consists of an InAs_{y}P_{1-y} compositionally step-graded region terminated with a buffer layer, a GaₓIn₁₋ₓAs active layer, and an InAs_{y}P_{1-y} cap. Lattice-mismatch introduces biaxial strain, which alters the correct condition for lattice matching the buffer layer to the unstrained active layer. The minority-carrier lifetime in these structures is related to the difference between the bulk misfit of the active layer and the in-plane misfit of the strained buffer layer. With fixed buffer thickness, the optimum degree of mismatch in the buffer needed to eliminate strain from the GaₓIn₁₋ₓAs active layer generally exceeds the bulk mismatch of the active layer by a fraction of the mismatch increment Δfₛₜₑₚ within the grade. Correspondingly, the alloy composition of the buffer layer is altered from that of the prior art to acheive the optimized structure. Further improvements of these structure can be realized by incorporating an unstrained, InAs_{y}P_{1-y} displacement layer in the intermediate region between the buffer and active layers.

The foregoing exemplary descriptions and the illustrative preferred embodiments of the present invention have been explained in the drawings and described in detail, with varying modifications and alternative embodiments being taught While the invention has been so shown, described and illustrated, it should be understood by those skilled in the art that equivalent changes in form and detail may be made therein without departing from the true spirit and scope of the invention, and that the scope of the present invention is to be limited only to the claims except as precluded by the prior art. Moreover, the invention, as disclosed herein, may be suitably practiced in the absence of the specific elements which are disclosed herein.

1. A heterostructure containing the semiconductor alloys GaₓIn₁₋ₓAs and InAs_{y}P_{1-y} for minimizing dislocations resulting from lattice mismatch of an active, heteroepitaxial layer, the heterostructure comprising:
a semi-insulating substrate;
a compositionally step-graded region terminated by a buffer layer;
a intermediate region;
an active layer; and
a capping layer.

2. The heterostructure of claim 1 wherein the substrate is constructed from InP.

3. The heterostructure of claim 1 wherein the step-graded region is constructed from InAs_{y}P_{1-y}.

4. The heterostructure of claim 3 wherein the composition within the InAs_{y}P_{1-y} step-graded region is varied incrementally thereby accommodating the mismatch of the active layer.

5. The heterostructure of claim 1 wherein the buffer layer is constructed from InAs_{y}P_{1-y}.

6. The heterostructure of claim 5 wherein the strained InAs_{y}P_{1-y} buffer layer is grown to a thickness of approximately one (1) μm.

7. The heterostructure of claim 1 wherein the active layer is constructed from GaₓIn₁₋ₓAs.

8. The heterostructure of claim 7 wherein the GaₓIn₁₋ₓAs active layer is deposited upon the buffer layer.

9. The heterostructure of claim 1 wherein the capping layer is constructed from InAs_{y}P_{1-y}.

10. The heterostructure of claim 9 wherein the InAs_{y}P_{1-y} capping layer is grown for electrical passivation.

11. The heterostructure of claim 1 wherein the active layer is constructed from epitaxial GaₓIn₁₋ₓAs with x<0.47, and the step-graded region and buffer layer are constructed from InAs_{y}P_{1-y}.

12. The heterostructure of claim 1 wherein each of the layers is deposited with a vapor-phase epitaxy technique.

13. A method for eliminating strain and dislocations resulting from lattice mismatch of a heteroepitaxial layer, the method comprising:
providing a semi-insulating substrate;
depositing a compositionally step-graded region on the semi-insulating substrate;
terminating the step-graded region with a buffer layer;
depositing an intermediate region on the buffer layer;
depositing an active layer on the buffer layer; and
depositing a capping layer on the active layer.

14. The method of claim 13 further comprising: constructing the substrate from InP.

15. The method of claim 13 further comprising: constructing the step-graded layer from InAs_{y}P_{1-y}.

16. The method of claim 15 further comprising: incrementally varying the composition y of the step-graded layer thereby accommodating the mismatch of the heteroepitaxial layer.

17. The method of claim 13 further comprising: constructing the buffer layer from InAs_{y}P_{1-y}.

18. The method of claim 17 further comprising: growing the strained InAs_{y}P_{1-y} buffer layer to a thickness of approximately one (1) μm.

19. The method of claim 13 further comprising: constructing the active layer from GaₓIn₁₋ₓAs.

20. The method of claim 19 further comprising: depositing the GaₓIn₁₋ₓAs active layer upon the buffer layer.

21. The method of claim 13 further comprising: constructing the capping layer from of InAs_{y}P_{1-y}.

22. The method of claim 21 further comprising: growing the InAs_{y}P_{1-y} capping layer for electrical passivation.

23. The method of claim 13 further comprising: depositing each layer by vapor-phase epitaxy.
